(19) United States
(12) Patent Application Publication
(10) Pub. No.: US 2024/0381749 A1
(43) Pub. Date: Nov. 14, 2024

(54) DISPLAY DEVICE

(71) Applicant: Samsung Display Co., LTD., Yongin-si (KR)

(72) Inventor: RANGKYUN MOK, Yongin-si (KR)

(21) Appl. No.: 18/402,310

(22) Filed: Jan. 2, 2024

(30) Foreign Application Priority Data
May 8, 2023 (KR) 10-2023-0059224

(51) Int. Cl. H10K 59/80; H10K 59/122; H10K 59/38

(52) U.S. Cl. CPC H10K 59/8794; H10K 59/122; H10K 59/38; H10K 59/873; H10K 59/8792

(57) ABSTRACT

A display device includes a lower electrode disposed on a substrate, an organic emission layer disposed on the lower electrode, an upper electrode disposed on the organic emission layer, a lower light control electrode disposed on the upper electrode, a heating layer disposed on the lower light control electrode and having a temperature which changes depending on an applied current, and a phase change layer disposed on the heating layer and having a transmittance which changes depending on the temperature of the heating layer.

This application claims priority to Korean Patent Application No. 10-2023-0059224, filed on May 8, 2023, and all the benefits accruing therefrom under 35 U.S.C. § 119, the content of which in its entirety is herein incorporated by reference.

### BACKGROUND

### 1. Field

Implementations of the inventive concept relate generally to a display device. More specifically, implementations of the inventive concept relate to a display device with controllable viewing angle.

### 2. Description of the Related Art

There is an increasing demand for personal display devices that allow users to control a viewing angle of an image as desired. A personal display device means that, when the user operates the display device in normal mode, the image is displayed with a relatively wide viewing angle, and when the user operates the display device in privacy mode, the image is displayed with a relatively narrow viewing angle.

### SUMMARY

Conventionally, in order to implement the personal display device, a method of additionally attaching a privacy protection film was used. However, this has the disadvantage that the user must manually attach and detach the privacy protection film.

Embodiments provide a display device.

A display device in an embodiment may include a lower electrode disposed on a substrate, an organic emission layer disposed on the lower electrode, an upper electrode disposed on the organic emission layer, a lower light control electrode disposed on the upper electrode, a heating layer disposed on the lower light control electrode and having a temperature which changes depending on an applied current, and a phase change layer disposed on the heating layer and having a transmittance which changes depending on the temperature of the heating layer.

In an embodiment, the phase change layer may include a chalcogenide material.

In an embodiment, the phase change layer may include germanium (Ge)-antimony (Sb)-telenium (Te).

In an embodiment, the display device may further include a pixel defining layer disposed on the lower electrode and accommodating the organic emission layer in an opening and a light-blocking pattern disposed on the pixel defining layer and overlapping the pixel defining layer. The phase change layer may overlap the light-blocking pattern.

In an embodiment, a width of the phase change layer may be greater than a width of the light-blocking pattern.

In an embodiment, the display device may further include a color filter disposed on the organic emission layer, overlapping the organic emission layer, and contacting the phase change layer.

In an embodiment, the display device may further include an optical interference layer disposed on the upper electrode and destructively interfering with a light reflected from the phase change layer.

In an embodiment, the display device may further include an encapsulation layer disposed on the optical interference layer.

In an embodiment, the optical interference layer may include an inorganic material and may be disposed on an entirety of the upper electrode.

In an embodiment, the display device may further include an upper light control electrode disposed on the phase change layer.

In an embodiment, the display device may further include an encapsulation layer disposed on the upper electrode, and the lower light control electrode may be disposed on an entirety of the encapsulation layer.

In an embodiment, the display device may further include an encapsulation layer disposed on the upper electrode, and the lower light control electrode may include a plurality of lower light control electrode patterns patterned on the encapsulation layer.

In an embodiment, the plurality of lower light control electrode patterns may be driven separately.

In an embodiment, the heating layer may include heating patterns patterned for each of the plurality of lower light control electrode patterns, and the phase change layer may include phase change patterns patterned for each of the heating patterns.

In an embodiment, the display device may further include a pixel defining layer disposed on the lower electrode and accommodating the organic emission layer in an opening and a light-blocking pattern disposed on the pixel defining layer and overlapping the pixel defining layer. The light-blocking pattern may be inserted between the phase change patterns.

In an embodiment, the display device may further include upper light control electrode patterns disposed on the phase change patterns and patterned for each of the phase change patterns.

In an embodiment, the display device may further include a transistor layer disposed under the lower electrode and providing a driving current to the lower electrode.

Therefore, a display device in an embodiment of the disclosure may include a light-emitting diode layer and a viewing angle control layer disposed on the light-emitting diode layer. The viewing angle control layer may control the viewing angle of the display device and may include a phase change layer including or consisting of a phase change material. The phase change layer may have a transmittance that changes depending on temperature, may be disposed on the organic emission layer, and may overlap the pixel defining layer. As the transmittance of the phase change layer changes in real time, the viewing angle of the display device may be adjusted in real time. Additionally, display devices in embodiments of the invention may be applied to organic light-emitting diode display (“OLED”), liquid crystal display (“LCD”), etc.

### BRIEF DESCRIPTION OF THE DRAWINGS

The accompanying drawings, which are included to provide a further understanding of the inventive concept and are incorporated in and constitute a part of this specification, illustrate embodiments of the inventive concept together with the description.

FIG. 1 is a cross-sectional view illustrating an embodiment of a display device according to the invention.

FIG. 2 is a cross-sectional view illustrating a transistor layer included in the display device of FIG. 1.

FIGS. 3 and 4 are cross-sectional views illustrating a light-emitting diode layer, an optical interference layer, an encapsulation layer, and a viewing angle control layer included in the display device of FIG. 1.

FIGS. 5 and 6 are diagrams illustrating changes in optical properties of a phase change layer included in the viewing angle control layer of FIG. 3.

FIGS. 7 to 13 are diagrams illustrating a method of manufacturing a light-emitting diode layer, an optical interference layer, an encapsulation layer, and a viewing angle control layer of FIG. 3.

FIG. 14 is a cross-sectional view illustrating another embodiment of a light-emitting diode layer, an optical interference layer, an encapsulation layer, and a viewing angle control layer included in a display device according to the disclosure.

### DETAILED DESCRIPTION

Illustrative, non-limiting embodiments will be more clearly understood from the following detailed description in conjunction with the accompanying drawings.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term such as “about” can mean within one or more standard deviations, or within +30%, 20%, 10%, 5% of the stated value, for example.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

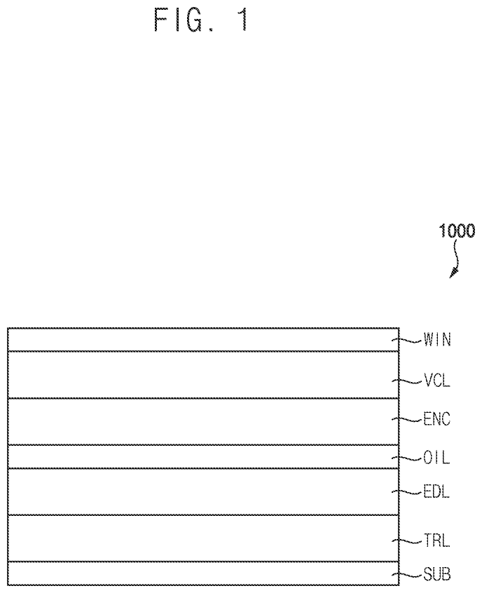

FIG. 1 is a cross-sectional view illustrating an embodiment of a display device according to the invention.

Referring to FIG. 1, a display device 1000 in an embodiment of the disclosure may include a substrate SUB, a transistor layer TRL, a light-emitting diode layer EDL, an optical interference layer OIL, an encapsulation layer ENC, a viewing angle control layer VCL, and a window WIN.

The substrate SUB may include an insulating material such as glass, quartz, or plastic. In addition, the substrate SUB may consist of a single layer or multiple layers by combining them.

The transistor layer TRL may be disposed on the substrate SUB. The transistor layer TRL may generate a driving current and may provide the driving current to the light-emitting diode layer EDL.

The light-emitting diode layer EDL may be disposed on the transistor layer TRL. The light-emitting diode layer EDL may emit light corresponding to the driving current.

The optical interference layer OIL may be disposed on the light-emitting diode layer EDL. The optical interference layer OIL may destructively interfere with light reflected from the viewing angle control layer VCL.

The encapsulation layer ENC may be disposed on the optical interference layer OIL. The encapsulation layer ENC may prevent moisture and/or oxygen from penetrating into the light-emitting diode layer EDL.

The viewing angle control layer VCL may be disposed on the encapsulation layer ENC. The viewing angle control layer VCL may transmit or reflect light emitted from the light-emitting diode layer EDL.

The window WIN may be disposed on the viewing angle control layer VCL. The window WIN may include or consist of glass, plastic, etc., and may protect the display device 1000 from impact.

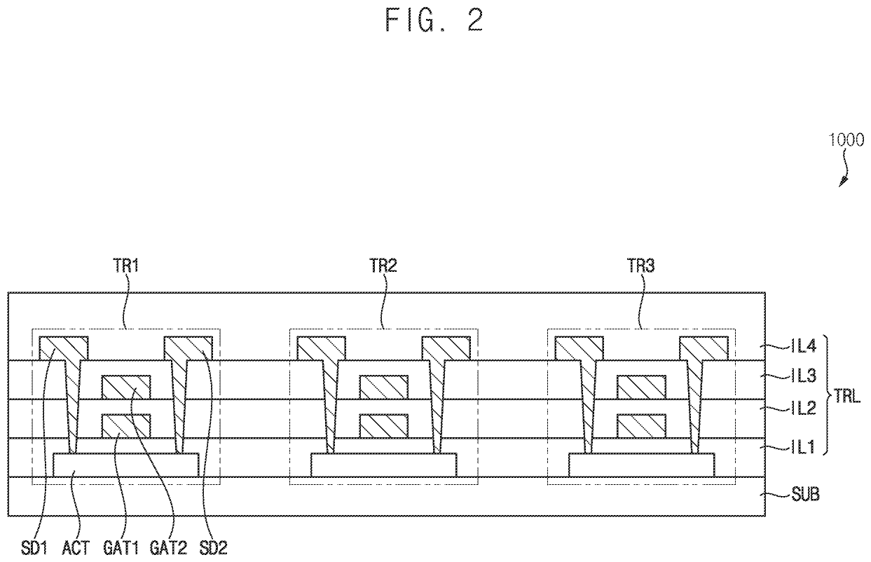

FIG. 2 is a cross-sectional view illustrating a transistor layer included in the display device of FIG. 1.

Referring to FIG. 2, the transistor layer TRL may include an active pattern ACT, a first insulating layer IL1, a first gate electrode GAT1, a second insulating layer IL2, a second gate electrode GAT2, a third insulating layer IL3, a first connection electrode SD1, a second connection electrode SD2, and a fourth insulating layer IL4.

The active pattern ACT, the first gate electrode GAT1, the second gate electrode GAT2, the first connection electrode SD1, and the second connection electrode SD2 may a first transistor TR1.

In addition, the transistor layer TRL may further include a second transistor TR2 and a third transistor TR3. Each of the second and third transistors TR2 and TR3 may have the same structure as the first transistor TR1. Each of the first to third transistors TR1, TR2, and TR3 may generate the driving current and implement one sub-pixel.

The active pattern ACT may be disposed on the substrate SUB. In an embodiment, the active pattern ACT may include or consist of a silicon semiconductor material or an oxide semiconductor material. In embodiments, the silicon semiconductor material that may be used as the active pattern ACT may include amorphous silicon and polycrystalline silicon. In embodiments, the oxide semiconductor material that may be used as the active pattern ACT may be InGaZnO (“IGZO”), InSnZnO (“ITZO”), etc. In addition, the oxide semiconductor material may further include indium (In), gallium (Ga), tin (Sn), zirconium (Zr), vanadium (V), hafnium (Hf), cadmium (Cd), germanium (Ge), chromium (Cr), titanium (Ti), and zinc (Zn). These may be used alone or in any combinations with each other.

The first insulating layer IL1 may cover the active pattern ACT and may be disposed on the substrate SUB. In an embodiment, the first insulating layer IL1 may include or consist of an insulating material. In embodiments, insulating materials that may be used as the first insulating layer IL1 may include silicon oxide, silicon nitride, and silicon oxynitride. These may be used alone or in any combinations with each other.

The first gate electrode GAT1 may be disposed on the first insulating layer IL1. In an embodiment, the first gate electrode GAT1 may include or consist of metal, alloy, conductive metal oxide, transparent conductive material, etc. In embodiments, materials that may be used as the first gate electrode GAT1 may include at least one of silver (Ag), an alloy including or consisting of at least one of silver, molybdenum (Mo), an alloy including or consisting of at least one of molybdenum, aluminum (Al), an alloy including or consisting of at least one of aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (“ITO”), indium zinc oxide (“IZO”), etc. These may be used alone or in any combinations with each other.

The second insulating layer IL2 may be disposed on the first insulating layer IL1. The second insulating layer IL2 may cover the first gate electrode GAT1. In an embodiment, the second insulating layer IL2 may include or consist of an insulating material. In embodiments, insulating materials that may be used as the second insulating layer IL2 may include silicon oxide, silicon nitride, and silicon oxynitride. These may be used alone or in any combinations with each other.

The second gate electrode GAT2 may be disposed on the second insulating layer IL2. In an embodiment, the second gate electrode GAT2 may include or consist of metal, alloy, conductive metal oxide, transparent conductive material, etc.

The third insulating layer IL3 may be disposed on the second insulating layer IL2. The third insulating layer IL3 may cover the second gate electrode GAT2. In an embodiment, the third insulating layer IL3 may include or consist of an insulating material.

The first and second connection electrodes SD1 and SD2 may be disposed on the third insulating layer IL3 and may contact the active pattern ACT. In an embodiment, the first and second connection electrodes SD1 and SD2 may include or consist of metal, alloy, conductive metal oxide, transparent conductive material, etc. In embodiments, materials that may be used as the first and second connection electrodes SD1 and SD2 may include silver (Ag), an alloy including or consisting of at least one of silver, molybdenum (Mo), an alloy including or consisting of at least one of molybdenum, aluminum (Al), an alloy including or consisting of at least one of aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (“ITO”), indium zinc oxide (“IZO”), etc. These may be used alone or in any combinations with each other.

The fourth insulating layer IL4 may be disposed on the third insulating layer IL3. The fourth insulating layer IL4 may cover the first and second connection electrodes SD1 and SD2. In an embodiment, the fourth insulating layer IL4 may include or consist of an insulating material.

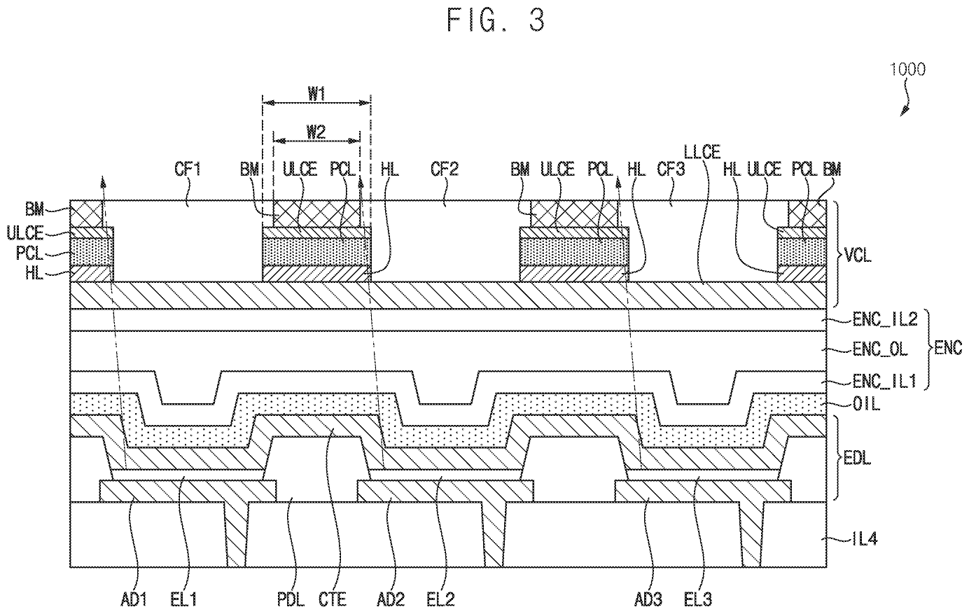

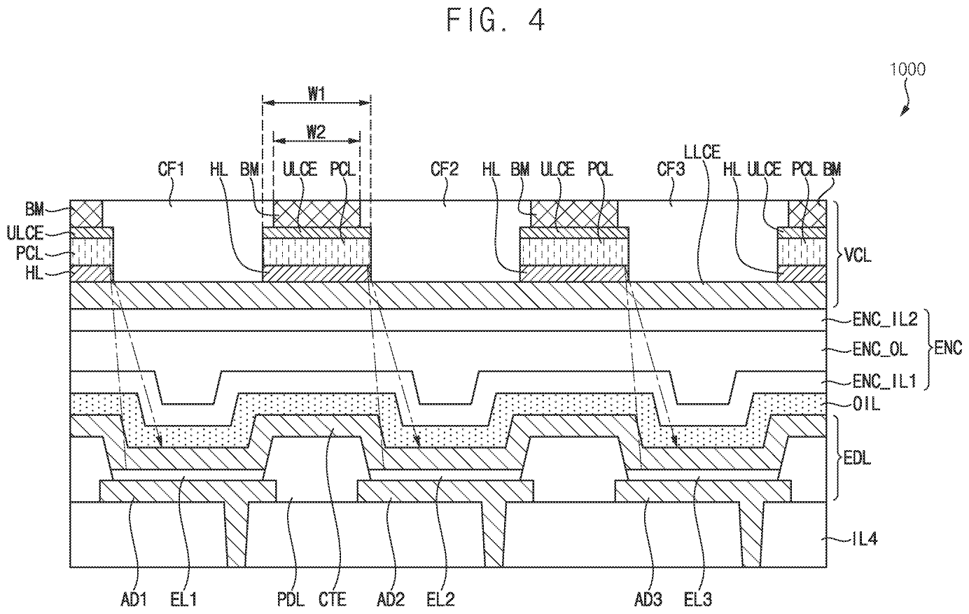

FIGS. 3 and 4 are cross-sectional views illustrating a light-emitting diode layer, an optical interference layer, an encapsulation layer, and a viewing angle control layer included in the display device of FIG. 1.

Referring to FIGS. 3 and 4, the light-emitting diode layer EDL may include a first lower electrode AD1, a second lower electrode AD2, a third lower electrode AD3, a pixel defining layer PDL, a first organic emission layer EL1, a second organic emission layer EL2, a third organic emission layer EL3, an upper electrode CTE. The encapsulation layer ENC may include a first inorganic encapsulation layer ENC_IL1, an organic encapsulation layer ENC_OL, and a second inorganic encapsulation layer ENC_IL2. The viewing angle control layer VCL may include a lower light control electrode LLCE, a heating layer HL, a phase change layer PCL, a first color filter CF1, a second color filter CF2, a third color filter CF3, and a light-blocking pattern BM.

The first lower electrode AD1 may be disposed on the fourth insulating layer IL4. In an embodiment, the first lower electrode AD1 may include or consist of metal, alloy, conductive metal oxide, transparent conductive material, etc. In embodiments, materials that may be used as the first lower electrode AD1 may include silver (Ag), an alloy including or consisting of at least one of silver, molybdenum (Mo), an alloy including or consisting of at least one of molybdenum, aluminum (Al), an alloy including or consisting of at least one of aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (“ITO”), indium zinc oxide (“IZO”), etc. These may be used alone or in any combinations with each other.

In an embodiment, the second lower electrode AD2 and the third lower electrode AD3 may be disposed on the fourth insulating layer IL4 and may be formed together with the first lower electrode AD1.

The pixel defining layer PDL may be disposed on the first to third lower electrodes AD1, AD2, and AD3, and may include an opening exposing each of the first to third lower electrodes AD1, AD2, and AD3 In an embodiment, the pixel defining layer PDL may include or consist of an organic material. In embodiments, organic materials that may be used as the pixel defining layer PDL may include photoresist, polyacrylic resin, polyimide resin, and acrylic resin. These may be used alone or in any combinations with each other.

The first organic emission layer EL1 may be disposed on the first lower electrode AD1 and may be accommodated in the opening. The first organic emission layer EL1 may include an organic compound that emits light when the driving current flows.

The second organic emission layer EL2 and the third organic emission layer EL3 may be disposed on the second lower electrode AD2 and the third lower electrode AD3, respectively. In an embodiment, the first to third organic emission layers EL1, EL2, and EL3 may emit red light, green light, and blue light, respectively, for example. However, the disclosure is not limited thereto, and the first to third organic emission layers EL1, EL2, and EL3 may emit various other color lights.

The upper electrode CTE may be disposed on the first to third organic emission layers EL1, EL2, and EL3.

The optical interference layer OIL may be disposed on the upper electrode CTE. In an embodiment, the optical interference layer OIL may be disposed on an entirety of the upper electrode CTE, for example. However, the invention is not limited to thereto.

In an embodiment, the optical interference layer OIL may destructively interfere with light reflected from the viewing angle control layer VCL. In an embodiment, the optical interference layer OIL may include a material with relatively low reflectivity. In embodiments, materials that may be used as the optical interference layer OIL may include indium (In), zinc (Zn), bismuth (Bi), ytterbium (Yb), and a compound of Bi and Yb (Yb/Bi), etc., for example. These may be used alone or in any combinations with each other.

In an embodiment, the optical interference layer OIL may have an appropriate thickness to destructively interfere with light reflected from the viewing angle control layer VCL. In an embodiment, the thickness of the optical interference layer OIL may be about 500 angstroms to 2500 angstroms, for example.

The first inorganic encapsulation layer ENC_IL1 may be disposed on the optical interference layer OIL. In an embodiment, the first inorganic encapsulation layer ENC_IL1 may include or consist of an inorganic material. In embodiments, inorganic materials that may be used as the first inorganic encapsulation layer ENC_IL1 may include silicon oxide, silicon nitride, and silicon oxynitride. These may be used alone or in any combinations with each other.

The organic encapsulation layer ENC_OL may be disposed on the first inorganic encapsulation layer ENC_IL1. In an embodiment, the organic encapsulation layer ENC_OL may include or consist of an organic material. In embodiments, organic materials that may be used as the organic encapsulation layer ENC_OL may include photoresist, polyacrylic resin, polyimide resin, and acrylic resin. These may be used alone or in any combinations with each other.

The second inorganic encapsulation layer ENC_IL2 may be disposed on the organic encapsulation layer ENC_OL. In an embodiment, the second inorganic encapsulation layer ENC_IL2 may include or consist of an inorganic material.

The lower light control electrode LLCE may be disposed on the second inorganic encapsulation layer ENC_IL2. In an embodiment, the lower light control electrode LLCE may be disposed on an entirety of the encapsulation layer ENC.

In an embodiment, the lower light control electrode LLCE may include or consist of a metal, alloy, conductive metal oxide, transparent conductive material, etc., and preferably may include or consist of a transparent conductive material that may transmit light. In embodiments, materials that may be used as the lower light control electrode LLCE may include silver (Ag), an alloy including or consisting of at least one of silver, molybdenum (Mo), an alloy including or consisting of molybdenum, aluminum (Al), an alloy including or consisting of at least one of aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (“ITO”), indium zinc oxide (“IZO”), etc. These may be used alone or in any combinations with each other.

The heating layer HL may be disposed on the lower light control electrode LLCE. A temperature of the heating layer HL may change depending on the current applied to the heating layer HL. Accordingly, the phase change layer PCL may be heated by the heating layer HL.

In an embodiment, the heating layer HL may include titanium nitride (TiN), titanium oxynitride (TiON), titanium aluminum nitride (TiAlN), titanium silicon nitride (TiSiN), tantalum aluminum nitride (TaAlN), tantalum silicon nitride (TaSiN), and silicon germanium (SiGe), for example.

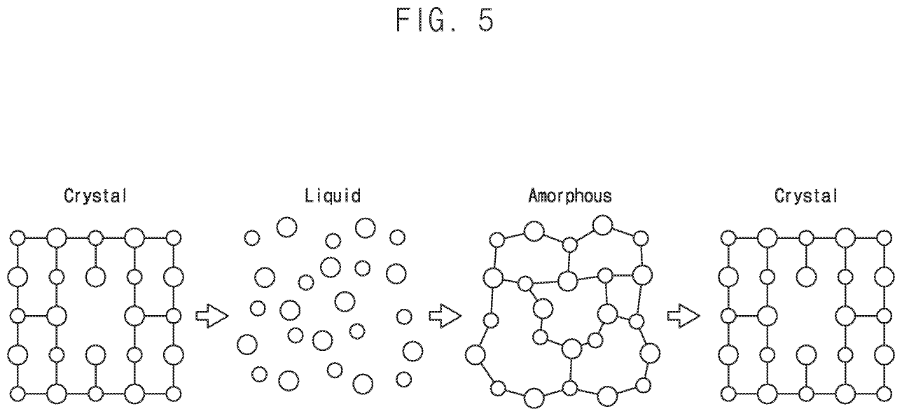

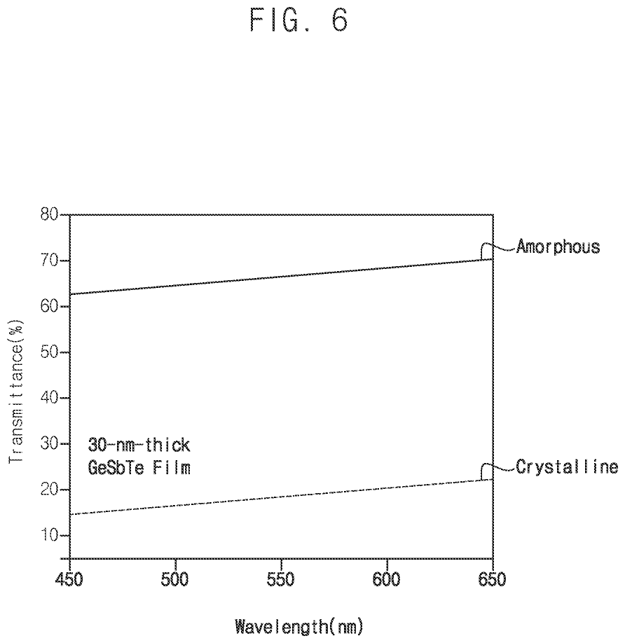

The phase change layer PCL may be disposed on the heating layer HL. A transmittance of the phase change layer PCL may change depending on the temperature of the heating layer HL. In an embodiment, the phase change layer PCL may include a chalcogenide-based material, for example. A description of the material forming the phase change layer PCL will be described later with reference to FIGS. 5 and 6.

The upper light control electrode ULCE may be disposed on the phase change layer PCL. In an embodiment, the upper light control electrode ULCE may be formed in a mesh shape.

In an embodiment, the upper light control electrode ULCE may include or consist of a metal, alloy, conductive metal oxide, transparent conductive material, etc., and preferably, may include or consist of a transparent conductive material that may transmit light. In embodiments, materials that may be used as the upper light control electrode ULCE may include silver (Ag), an alloy including or consisting of at least one of silver, molybdenum (Mo), an alloy including or consisting of at least one of molybdenum, aluminum (Al), an alloy including or consisting of at least one of aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (“ITO”), indium zinc oxide (“IZO”), etc. These may be used alone or in any combinations with each other.

The lower light control electrode LLCE and the upper light control electrode ULCE may provide current to the heating layer HL, and the temperature of the heating layer HL may change depending on the current. The transmittance of the phase change layer PCL may change depending on the temperature.

In an embodiment, as shown in FIG. 3, the phase change layer PCL may transmit light depending on the temperature of the heating layer HL. Accordingly, light with a relatively high viewing angle among the light emitted from the first to third organic emission layers EL1, EL2, and EL3 may be transmitted through the phase change layer PCL. In this case, the viewing angle of the display device 1000 may increase.

In an embodiment, as shown in FIG. 4, the phase change layer PCL may reflect light depending on the temperature of the heating layer HL. Accordingly, light with a relatively high viewing angle among the light emitted from the first to third organic emission layers EL1, EL2, and EL3 may be reflected by the phase change layer PCL. Light reflected from the phase change layer PCL may be absorbed by the optical interference layer OIL. In this case, the viewing angle of the display device 1000 may decrease.

The first color filter CF1 may be disposed on the lower light control electrode LLCE and may overlap the first organic emission layer EL1. In an embodiment, the first color filter CF1 may contact the phase change layer PCL. The first color filter CF1 may transmit light having a preset color.

The second color filter CF2 and the third color filter CF3 may be disposed on the second organic emission layer EL2 and the third organic emission layer EL3, respectively. In an embodiment, the first to third color filters CF1, CF2, and CF3 may transmit red light, green light, and blue light, respectively, for example.

The light-blocking pattern BM may be disposed on the upper light control electrode ULCE and may overlap the pixel defining layer PDL. The light-blocking pattern BM may include or consist of a light-blocking material that absorbs and/or blocks light.

In an embodiment, a size of the phase change layer PCL may be appropriately set to control the viewing angle of the display device 1000. In an embodiment, a first width W1 of the phase change layer PCL may be greater than a second width W2 of the light-blocking pattern BM. Accordingly, as shown in FIG. 4, the phase change layer PCL may block light before the light-blocking pattern BM, for example.

FIGS. 5 and 6 are diagrams illustrating changes in optical properties of a phase change layer included in the viewing angle control layer of FIG. 3.

Referring to FIGS. 5 and 6, in an embodiment, the phase change layer PCL may include a chalcogenide-based material as a phase change material.

A crystal state of the phase change material may change depending on the temperature, and the transmittance may change depending on the crystal state. In detail, the phase change material may be in an amorphous state at relatively low temperatures and in a crystalline state at relatively high temperatures. Additionally, the phase change material may have a substantially fast response speed (e.g., about 30 nanosecond (ns) to 1 millisecond (ms)) and may be driven at relatively low power (e.g., about 50 microampere (μA) to 2 milliampere (mA)).

In an embodiment, the phase change layer PCL may include germanium (Ge)-antimony (Sb)-telenium (Te), for example. A material including or consisting of Ge—Sb—Te enters a crystalline state when the temperature exceeds a predetermined temperature, and enters an amorphous state when the temperature falls below the predetermined temperature. As described above, the amorphous state may be an opaque state that does not transmit light, and the crystalline state may be a transparent state that transmits light. Accordingly, the transmission of light may be controlled by a phase change material including or consisting of Ge—Sb—Te. In an embodiment, a material including or consisting of Ge—Sb—Te may change phase based on a predetermined temperature of about 500 degrees Celsius (° C.) to about 600° C., but the predetermined temperature may change depending on the predetermined composition, for example. In addition, phase change materials including or consisting of Ge—Sb—Te may have a compound or alloy structure, and embodiments of compounds include Ge2Sb2Te5, which is a ternary compound, (GeSn) SbTe, and GeSb(SeTe), which are quaternary compounds.

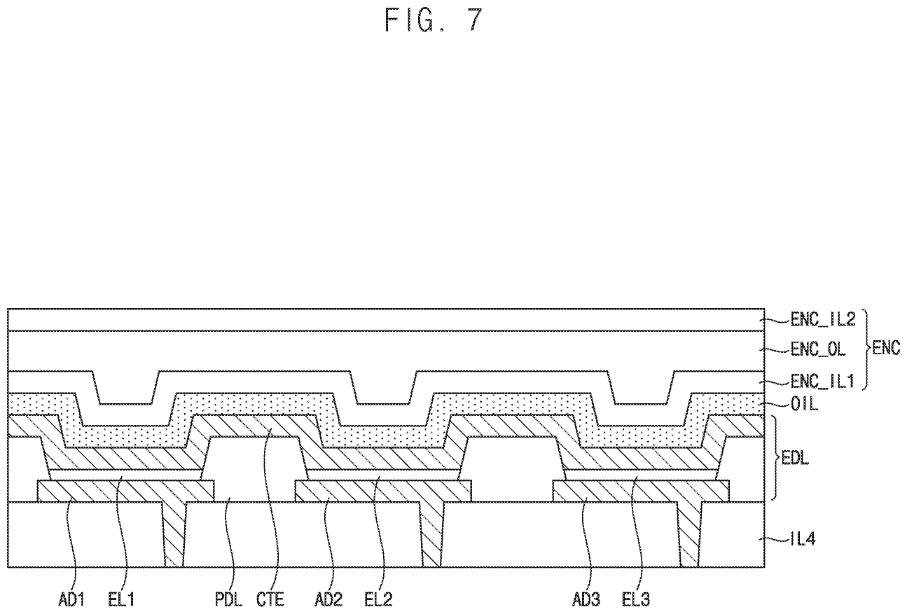

FIGS. 7 to 13 are diagrams illustrating a method of manufacturing a light-emitting diode layer, an optical interference layer, an encapsulation layer, and a viewing angle control layer of FIG. 3.

Referring to FIG. 7, the light-emitting diode layer EDL, the optical interference layer OIL, and the encapsulation layer ENC may be sequentially formed on the fourth insulating layer IL4.

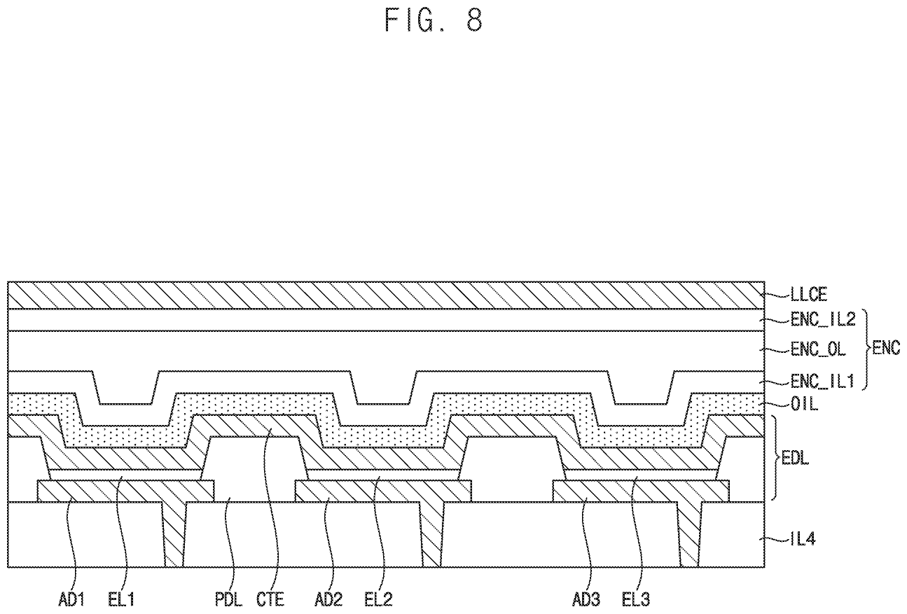

Referring to FIG. 8, the lower light control electrode LLCE may be formed on the encapsulation layer ENC. In an embodiment, the lower light control electrode LLCE may be formed entirely on the encapsulation layer ENC.

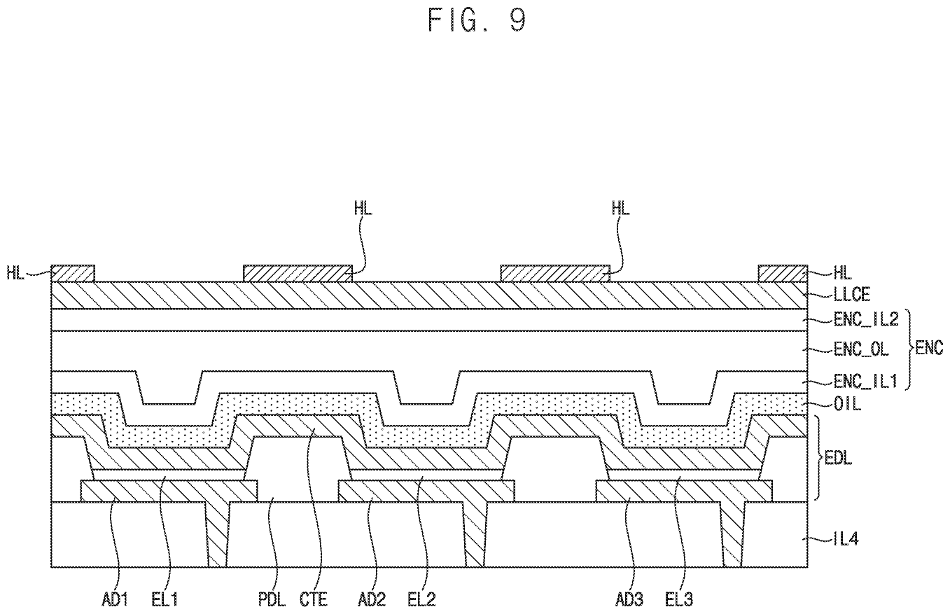

Referring to FIG. 9, the heating layer HL may be formed on the lower light control electrode LLCE.

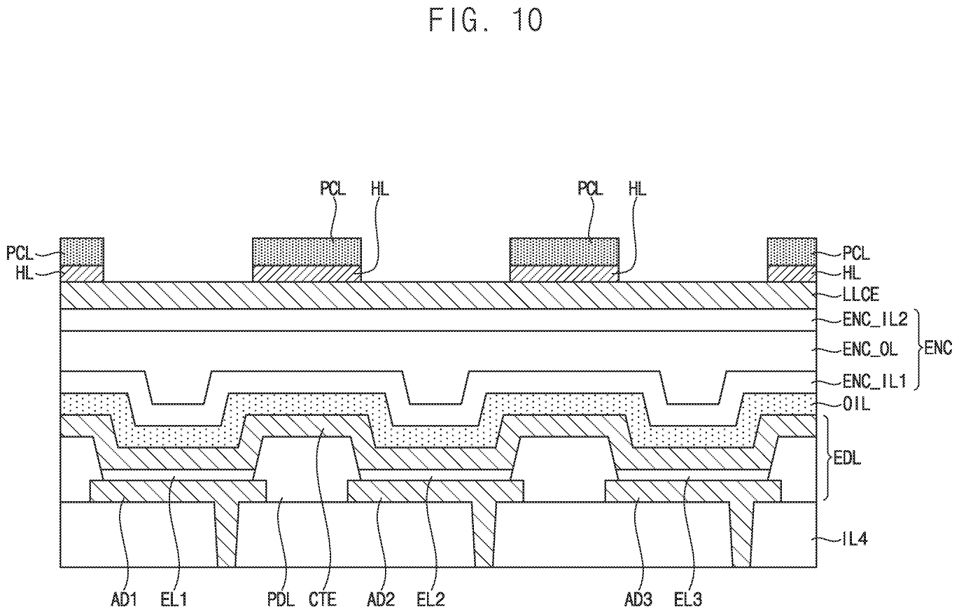

Referring to FIG. 10, the phase change layer PCL may be formed on the heating layer HL.

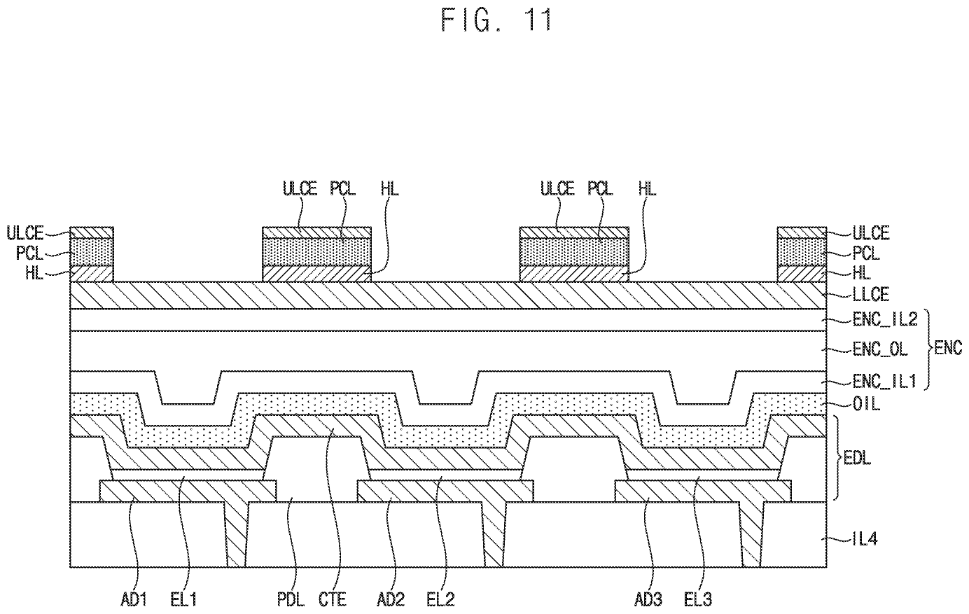

Referring to FIG. 11, the upper light control electrode ULCE may be formed on the phase change layer PCL. In an embodiment, the heating layer HL, the phase change layer PCL, and the upper light control electrode ULCE may be formed in a mesh shape, but the invention is not limited thereto.

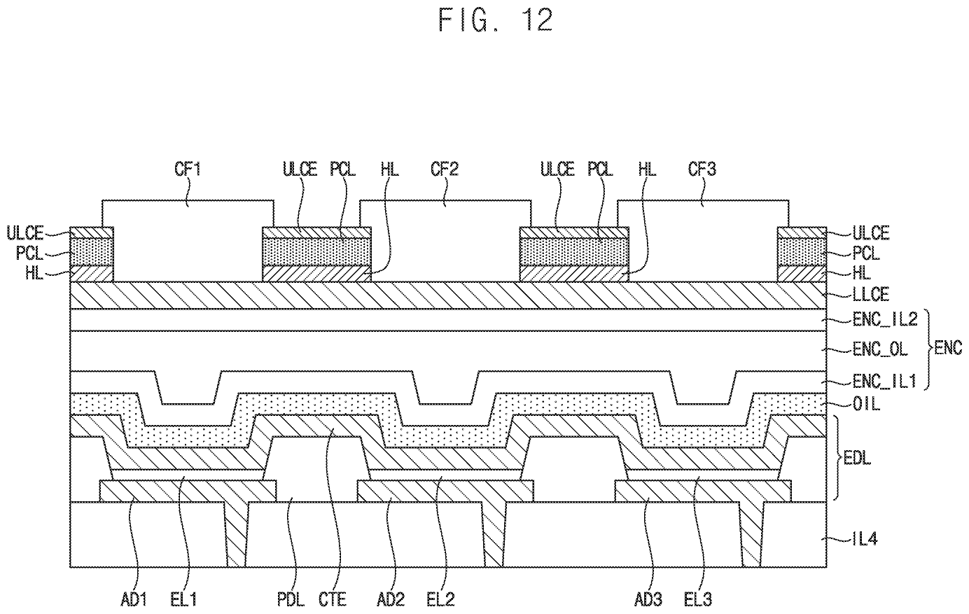

Referring to FIG. 12, the first to third color filters CF1, CF2, and CF3 may be formed on the upper light control electrode ULCE.

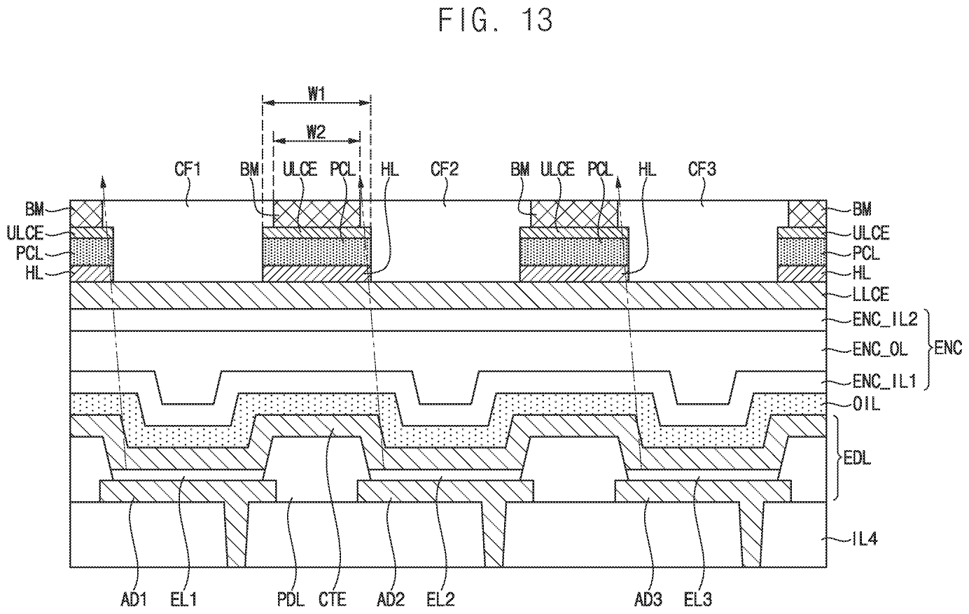

Referring to FIG. 13, the light-blocking pattern BM may be formed on the upper light control electrode ULCE. In an embodiment, the light-blocking pattern BM may be formed after the first to third color filters CF1, CF2, and CF3 are formed, but the invention is not limited thereto.

The display device 1000 in an embodiment of the disclosure may include the light-emitting diode layer EDL and the viewing angle control layer VCL disposed on the light-emitting diode layer EDL. The viewing angle control layer VCL may control the viewing angle of the display device 1000 and may include the phase change layer PCL including the phase change material. The phase change layer PCL may have a transmittance that changes depending on temperature, may be disposed on the first to third organic emission layers EL1, EL2, and EL3, and may overlap with the pixel defining layer PDL. As the transmittance of the phase change layer PCL changes in real time, the viewing angle of the display device 1000 may be controlled in real time. In addition, the display device 1000 has been mainly described as an organic light-emitting display device (“OLED”), but the display device in embodiments of the invention is not limited thereto and may also be applied to, e.g., a liquid crystal display device (“LCD”).

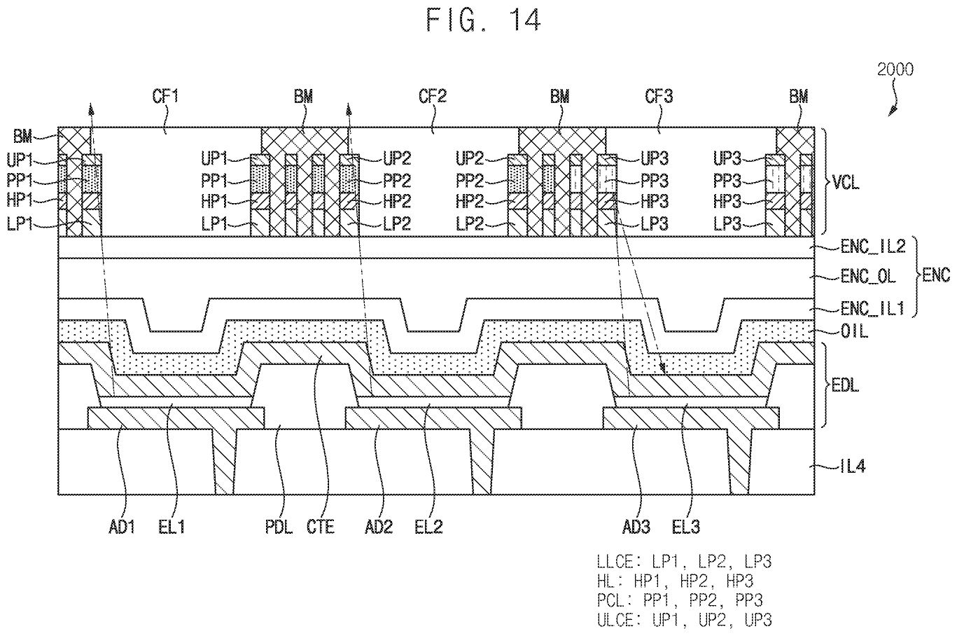

FIG. 14 is a cross-sectional view illustrating another embodiment of a light-emitting diode layer, an optical interference layer, an encapsulation layer, and a viewing angle control layer included in a display device according to the disclosure.

Referring to FIG. 14, a display device 2000 in another embodiment of the disclosure may include a substrate (e.g., the substrate SUB in FIG. 1), a transistor layer (e.g., the transistor layer TRL in FIG. 1), a light-emitting diode layer EDL, an optical interference layer OIL, an encapsulation layer ENC, a viewing angle control layer VCL, and a window WIN (refer to FIG. 1). However, the display device 2000 may be substantially the same as the display device 1000 described above with reference to FIGS. 1 to 4 except for the viewing angle control layer VCL.

The viewing angle control layer VCL may include a lower light control electrode LLCE, a heating layer HL, a phase change layer PCL, and an upper light control electrode ULCE.

The lower light control electrode LLCE may include a plurality of lower light control electrode patterns patterned on the encapsulation layer ENC. In an embodiment, the lower light control electrode LLCE may include a first lower light control electrode pattern LP1, a second lower light control electrode pattern LP2, and a third lower light control electrode pattern LP3, for example.

The first lower light control electrode pattern LP1 may be adjacent to the first organic emission layer EL1 in a plan view, the second lower light control electrode pattern LP2 may be adjacent to the second organic emission layer EL2 in a plan view, and the third lower light control electrode pattern LP3 may be adjacent to the third organic emission layer EL3 in a plan view.

In an embodiment, the first to third lower light control electrode patterns LP1, LP2, and LP3 may be driven separately. In an embodiment, a relatively high voltage may be applied to the first and second lower light control electrode patterns LP1 and LP2, and a relatively low voltage may be applied to the third lower light control electrode pattern LP3, for example.

The heating layer HL may include heating patterns patterned for each of the lower light control electrode patterns. In an embodiment, the heating layer HL may include a first heating pattern HP1, a second heating pattern HP2, and a third heating pattern HP3, for example.

The first heating pattern HP1 may be disposed on the first lower light control electrode pattern LP1, the second heating pattern HP2 may be disposed on the second lower light control electrode pattern LP2, and the third heating pattern HP3 may be disposed on the third lower light control electrode pattern LP3.

In an embodiment, temperatures of the first to third heating patterns HP1, HP2, and HP3 may be different from each other. In an embodiment, the first and second heating patterns HP1 and HP2 may have relatively high temperatures, and the third heating pattern HP3 may have a relatively low temperature, for example.

The phase change layer PCL may include phase change patterns patterned for each of the heating patterns. In an embodiment, the phase change layer PCL may include a first phase change pattern PP1, a second phase change pattern PP2, and a third phase change pattern PP3, for example.

The first phase change pattern PP1 may be disposed on the first heating pattern HP1, the second phase change pattern PP2 may be disposed on the second heating pattern HP2, and the third phase change pattern PP3 may be disposed on the third heating pattern HP3.

In other words, the first phase change pattern PP1 may be adjacent to the first organic emission layer EL1 in a plan view, the second phase change pattern PP2 may be adjacent to the second organic emission layer EL2 in a plan view, and the third phase change pattern PP3 may be adjacent to the third organic emission layer EL3 in a plan view.

In an embodiment, the transmittance of the first to third phase change patterns PP1, PP2, and PP3 may be different from each other. In an embodiment, the first and second phase change patterns PP1 and PP2 may have relatively high transmittance, and the third phase change pattern PP3 may have relatively low transmittance, for example. Accordingly, among the light emitted from the first organic emission layer EL1, light with a relatively high viewing angle may be transmitted through the first phase change pattern PP1. Among the light emitted from the second organic emission layer EL2, light with a relatively high viewing angle may be transmitted through the second phase change pattern PP2. Among the light emitted from the third organic emission layer EL3, light with a relatively high viewing angle may be reflected by the third phase change pattern PP3.

The light-blocking pattern BM may be disposed on the upper light control electrode ULCE and may overlap the pixel defining layer PDL. In an embodiment, the upper light control electrode ULCE may include a first upper light control electrode pattern UP1, a second upper light control electrode pattern UP2 and a third upper light control electrode pattern UP3 respectively disposed on the first phase change pattern PP1, the second phase change pattern PP2 and the third phase change pattern PP3. In an embodiment, as shown in FIG. 14, the light-blocking pattern BM may be inserted between the phase change patterns.

Although illustrative embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A display device comprising:
a lower electrode disposed on a substrate;
an organic emission layer disposed on the lower electrode;
an upper electrode disposed on the organic emission layer;
a lower light control electrode disposed on the upper electrode;
a heating layer disposed on the lower light control electrode and having a temperature which changes depending on an applied current; and
a phase change layer disposed on the heating layer and having a transmittance which changes depending on the temperature of the heating layer.

2. The display device of claim 1, wherein the phase change layer includes a chalcogenide material.

3. The display device of claim 2, wherein the phase change layer includes germanium (Ge)-antimony (Sb)-telenium (Te).

4. The display device of claim 1, further comprising:
a pixel defining layer disposed on the lower electrode and accommodating the organic emission layer in an opening; and
a light-blocking pattern disposed on the pixel defining layer and overlapping the pixel defining layer,
wherein the phase change layer overlaps the light-blocking pattern.

5. The display device of claim 4, wherein a width of the phase change layer is greater than a width of the light-blocking pattern.

6. The display device of claim 1, further comprising:
a color filter disposed on the organic emission layer, overlapping the organic emission layer, and contacting the phase change layer.

7. The display device of claim 1, further comprising:
an optical interference layer disposed on the upper electrode and destructively interfering with a light reflected from the phase change layer.

8. The display device of claim 7, further comprising:
an encapsulation layer disposed on the optical interference layer.

9. The display device of claim 7, wherein the optical interference layer includes an inorganic material and is disposed on an entirety of the upper electrode.

10. The display device of claim 1, further comprising:
an upper light control electrode disposed on the phase change layer.

11. The display device of claim 1, further comprising:
an encapsulation layer disposed on the upper electrode,
wherein the lower light control electrode is disposed on an entirety of the encapsulation layer.

12. The display device of claim 1, further comprising:
an encapsulation layer disposed on the upper electrode,
wherein the lower light control electrode includes a plurality of lower light control electrode patterns patterned on the encapsulation layer.

13. The display device of claim 12, wherein the plurality of lower light control electrode patterns is driven separately.

14. The display device of claim 12, wherein the heating layer includes heating patterns patterned for each of the plurality of lower light control electrode patterns, and
the phase change layer includes phase change patterns patterned for each of the heating patterns.

15. The display device of claim 14, further comprising:
a pixel defining layer disposed on the lower electrode and accommodating the organic emission layer in an opening; and
a light-blocking pattern disposed on the pixel defining layer and overlapping the pixel defining layer,
wherein the light-blocking pattern is inserted between the phase change patterns.

16. The display device of claim 14, further comprising:
upper light control electrode patterns disposed on the phase change patterns and patterned for each of the phase change patterns.

17. The display device of claim 1, further comprising:
a transistor layer disposed under the lower electrode and providing a driving current to the lower electrode.
